(19) United States
(12) Patent Application Publication
(10) Pub. No.: US 2007/0105270 A1
(43) Pub. Date: May 10, 2007

(54) Packaging methods

(75) Inventor: Chien Chen Lee, Hsinchu County (TW)

Correspondence Address: QUINTERO LAW OFFICE, PC, 2210 MAIN STREET, SUITE 200, SANTA MONICA, CA, 90405, US

(73) Assignee: AIROHA TECHNOLOGY CORP., HSINCHU (TW)

(21) Appl. No.: 11/348,935

(22) Filed: Feb. 6, 2006

(30) Foreign Application Priority Data
Nov. 10, 2005 (TW) TW94139456

(51) Int. Cl. H01L 21/00

(52) U.S. Cl. 438/106

(57) ABSTRACT

Packaging method. The method includes providing a conductive substrate comprising top and bottom surfaces, forming a first circuit layer of a package substrate and then packaging an active device overlying the top surface, and forming other circuit layers and a contact pad of the package substrate overlying the bottom surface.

### BACKGROUND OF THE INVENTION

1. Field of the Invention

The invention relates to package technology and in particular to integration of fabrication methods of layered leadframes and encapsulating processes.

2. Description of the Related Art

Due to the demand for high-frequency, high-speed system-in-package (SIP), a small-aspect package design capable of effective heat dissipation and excellent electrical performance is necessary. Thus, package technology is a critical issue in SIP design. QFN (quad flat no-lead), capable of low pin inductance, is a widely anticipated technology, which utilizes a lead frame as a substrate.

A lead frame for QFN has a die paddle, attaching a chip thereto, and a plurality of leads beyond the die paddle. The chip has a plurality of terminals respectively electrically connecting the corresponding leads. An encapsulant covers the chip and respectively exposes the ends of the leads. The lead ends and the encapsulant are approximately coplanar, achieving a QFN package.

A QFN package has smaller aspect and better electrical performance than other package types. In a printed circuit board assembly (PBCA) process, QFN packages and passive devices are individually disposed on a PCB, resulting in the necessity to design PCB wirings to electrically connect corresponding QFN packages and passive devices. The required wirings may enlarge the PCB and/or wiring density thereof, which may cause crosstalk therebetween.

### BRIEF SUMMARY OF THE INVENTION

Packaging methods are provided.

The invention provides a packaging method. First, a conductive substrate comprising a top surface and bottom surface is provided. A base embryo and a first wiring pattern layer are then formed beyond the base embryo overlying the top surface of the conductive substrate. Next, an active device is electrically connected to the first wiring pattern layer. Next, an encapsulant is formed overlying the top surface of the conductive substrate, encapsulating the active device and the first wiring pattern layer. Next, the conductive substrate between the base embryo and the first wiring pattern layer is removed. The remaining conductive substrate underlying the base embryo becomes part thereof. Parts of the remaining conductive substrate become a conducting device and a pad embryo electrically connecting the first wiring pattern layer. Next, a first dielectric layer is formed among the base embryo, the conducting device, and the pad embryo. Next, the base embryo and pad embryo are thickened, and a second wiring pattern layer is formed overlying the first dielectric layer. Further, a second dielectric layer is formed among the base embryo, the second wiring pattern layer, and the pad embryo. Finally, the base embryo and pad embryo are thickened, respectively acting as an active device base and a pad.

The invention further provides another packaging method. First, a conductive substrate comprising a top surface and bottom surface is provided. A base embryo and a first wiring pattern layer, comprising a plurality of traces, are then formed beyond the base embryo overlying the top surface of the conductive substrate. Next, a passive device is electrically connected between at least two of the traces. Next, an active device is electrically connected to the first wiring pattern layer. Next, an encapsulant is formed overlying the top. surface of the conductive substrate, encapsulating the passive device, the active device, and the first wiring pattern layer. Next, the conductive substrate between the base embryo and the first wiring pattern layer is removed. The remaining conductive substrate underlying the base embryo becomes part thereof. Parts of the remaining conductive substrate become a conducting device and a pad embryo electrically connecting the first wiring pattern layer. Next, a first dielectric layer is formed among the base embryo, the conducting device, and the pad embryo. Next, the base embryo and pad embryo are thickened, and a second wiring pattern layer is formed overlying the first dielectric layer. Further, a second dielectric layer is formed among the base embryo, the second wiring pattern layer, and the pad embryo. Finally, the base embryo and pad embryo are thickened, respectively acting as an active device base and a pad.

Further scope of the applicability of the invention will become apparent from the detailed description given hereinafter. It should be understood, however, that the detailed description and specific examples, while indicating preferred embodiments of the invention, are given by way of illustration only, since various changes and modifications within the spirit and scope of the invention will become apparent to those skilled in the art from this detailed description.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIGS. 1A through 1M are cross-sections of flows of a packaging method of a first embodiment of the invention; and

FIGS. 2A through 2K are cross-sections of flows of a packaging method of a second embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

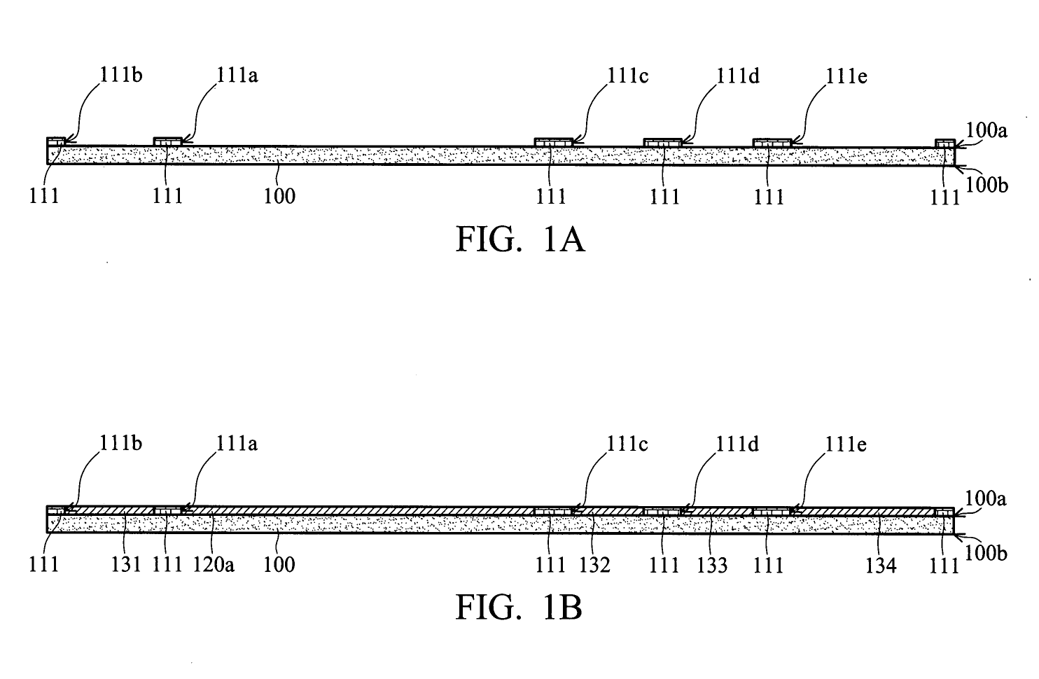

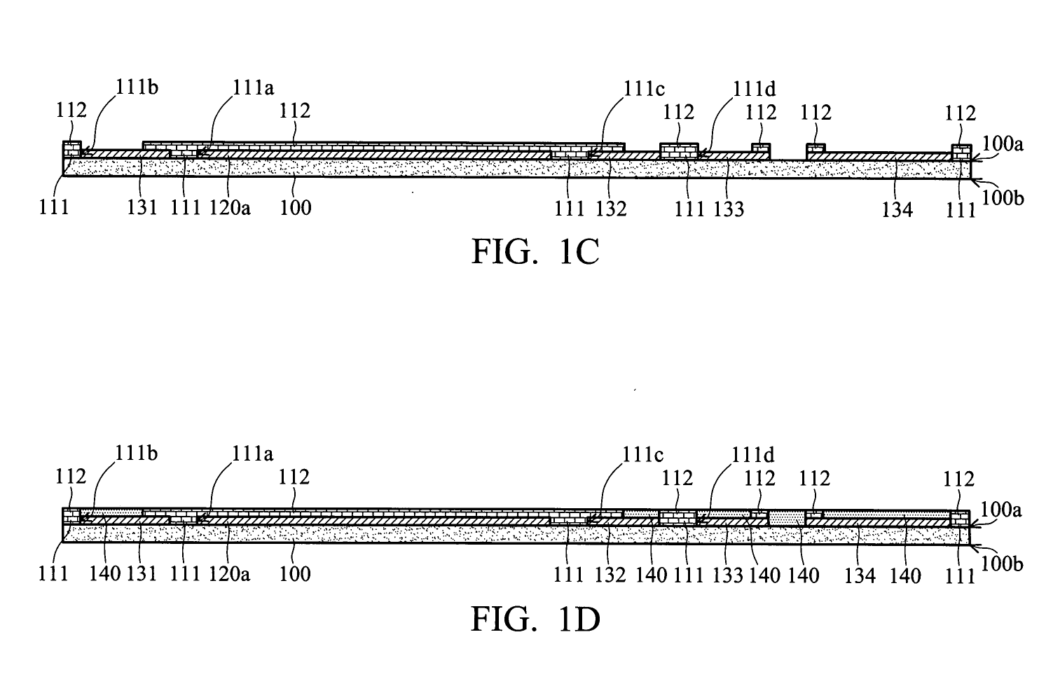

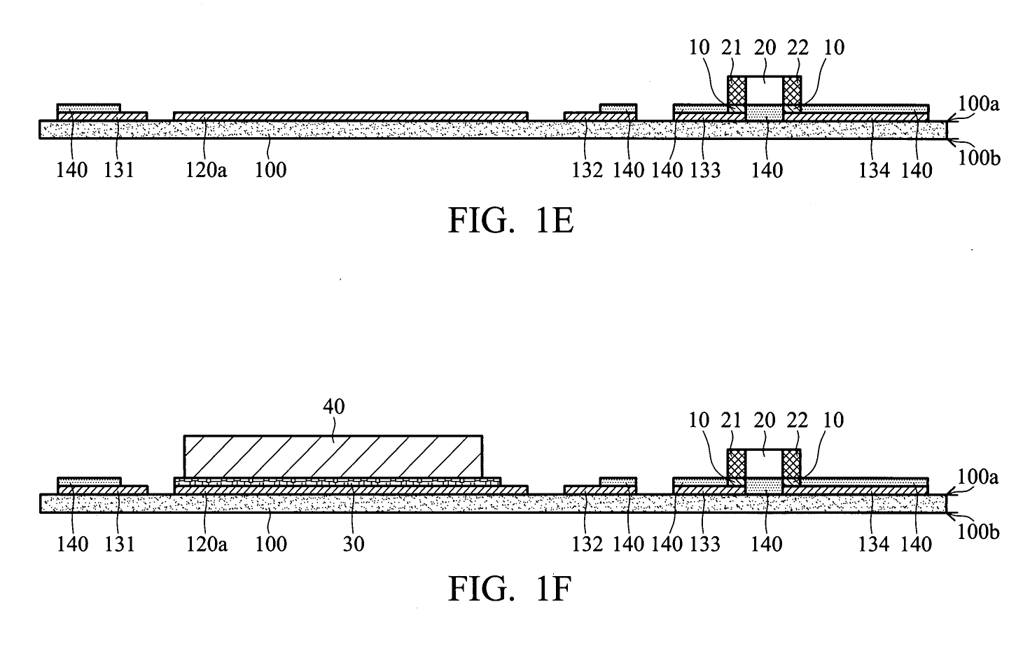

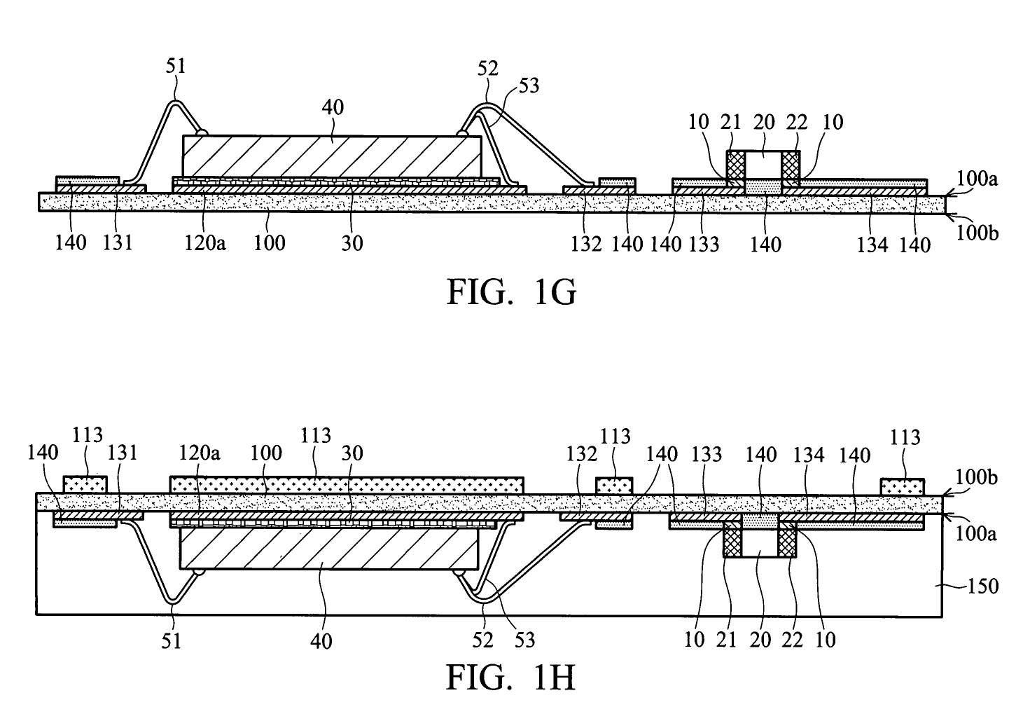

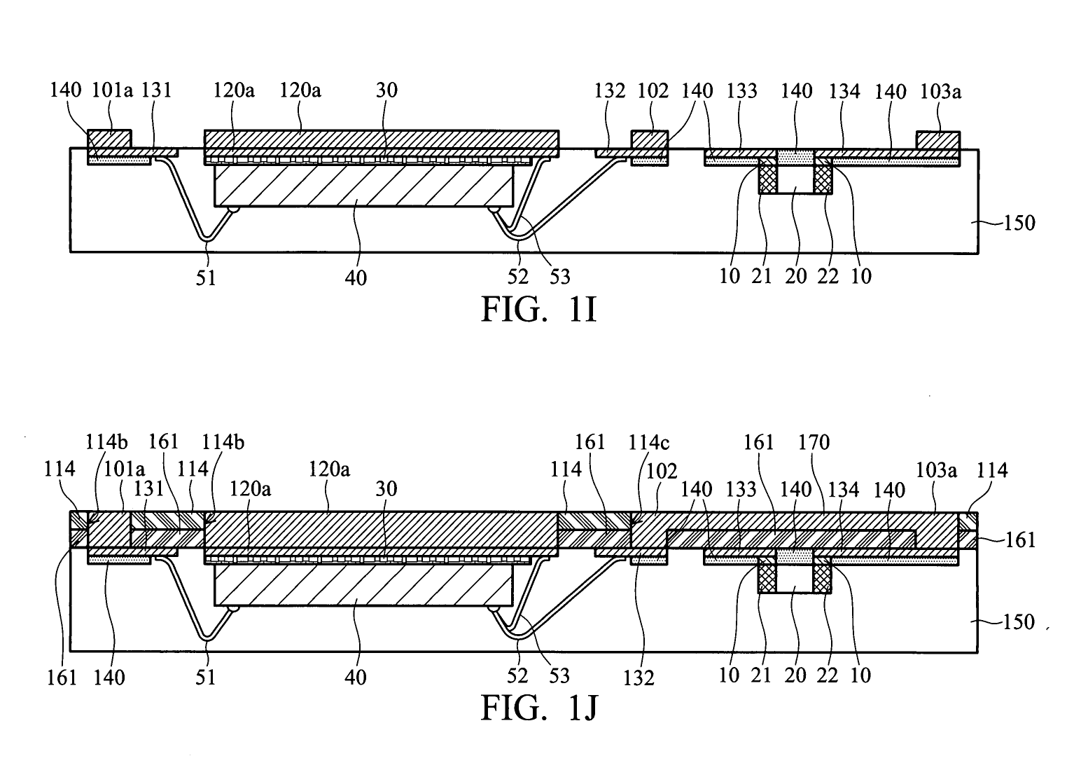

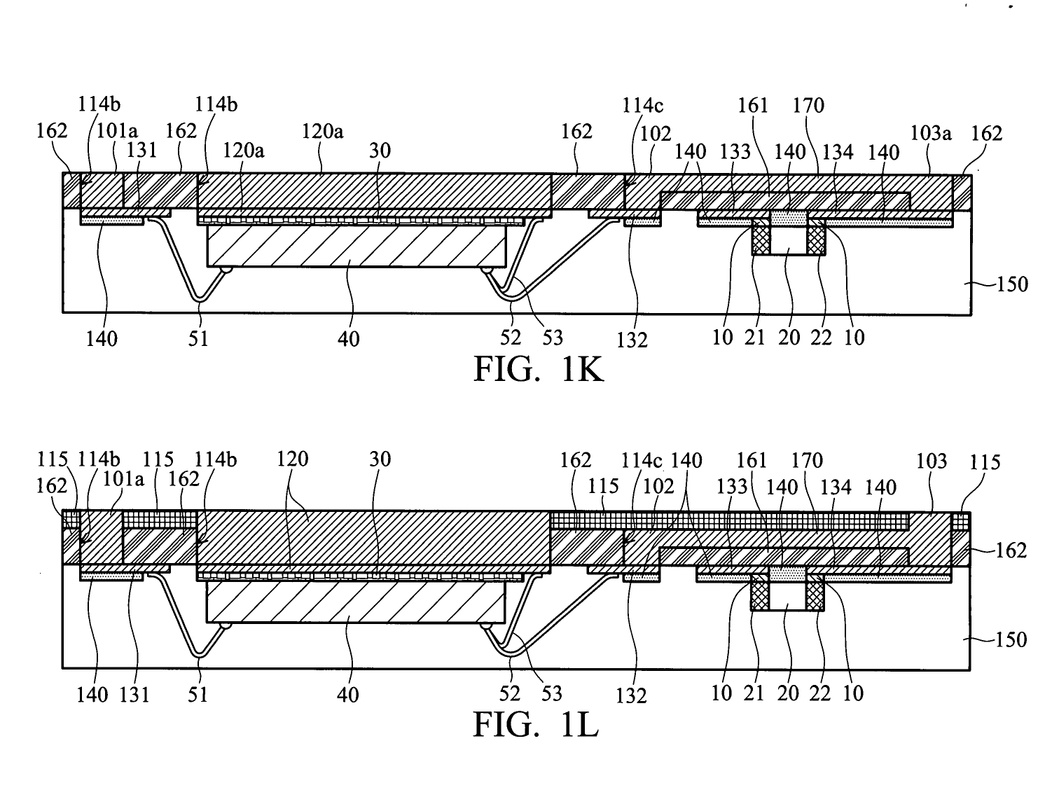

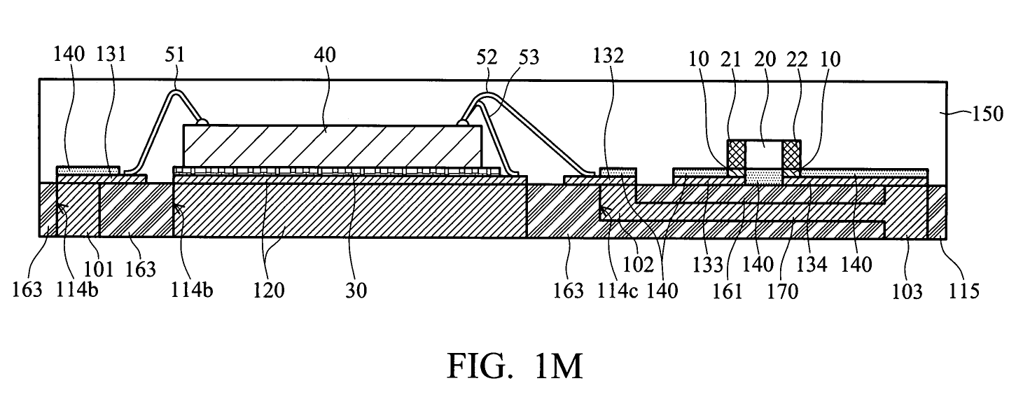

In FIGS. 1A through 1M, cross-sections of a packaging method of a first embodiment of the invention are shown.

In FIG. 1A, a conductive substrate 100, preferably copper, is provided. The conductive substrate 100 comprises a top surface 100a and bottom surface 100b.

A base embryo 120a and a first wiring pattern layer are formed overlying the top surface 100a of the conductive substrate 100 as shown in FIGS. 1A and 1B. Note that the steps shown in FIGS. 1A and 1B are exemplary, and not intended to limit the scope of the invention. Those skilled in the art will recognize the possibility of using various methods to achieve the base embryo 120a and the first wiring pattern layer shown in FIG. 1B.

In FIG. 1A, a first patterned mask layer 111, comprising an opening 111a exposing a predetermined region for an active device base 120 (shown in FIG. 1L), and openings 111b through 111e respectively exposing predetermined regions for every trace in the first wiring pattern layer, is formed overlying the top surface 100a of the conductive substrate 100. The first patterned mask layer 111 is typically formed by coating a resist layer, followed by exposure and development.

In FIG. 1B, the base embryo 120a and traces 131 through 134 of the first wiring pattern layer are formed overlying the exposed top surface 100a of the conductive substrate 100 by electroplating, electroless plating, or other methods. The first wiring pattern layer is formed beyond the base embryo 120a and may comprise a plurality of traces as desired. In this embodiment, the first wiring pattern layer comprises four traces 131 through 134. The base embryo 120a and the first wiring pattern layer are preferably substantially the same material as the conductive substrate 100, such as copper.

Next, an optional protection layer such as a solder mask can be formed overlying the first wiring pattern layer. The protection layer may be formed overlying the base embryo 120a when an active device is attached by flip chip technology, for example. In this embodiment, formation of the protection layer overlying the first wiring pattern layer is exemplified.

In FIG. 1C, a second patterned mask layer or stencil layer 112 is formed overlying the base embryo 120a and the first wiring pattern layer, followed by forming a protection layer 140 overlying the first wiring pattern layer as shown in FIG. 1D by a method such as stencil printing or other.

In some embodiments, the protection layer is not formed and the first patterned mask layer 111 is removed, followed by attachment of a passive device.

Next, following that shown in FIG. 1D, the second patterned mask layer or stencil layer 112 is removed. The exposed first wiring pattern layer acts as terminals for electrical connection to the subsequently described active and passive devices. In some cases, a layer (not shown) for anti-corrosion or solder enhancement such as a nickel/gold layer can be coated on the terminals. Further, the removal of the first patterned mask layer 111 can be performed before or after the removal of the second patterned mask layer or stencil layer 112 as desired.

In FIG. 1E, a passive device 20 such as a capacitor, a resistor, an inductor, or other device is electrically connected between at least two of the traces 131 through 134. In this embodiment, the passive device 20 is electrically connected between the traces 133 and 134, and preferably comprises terminals 21 and 22 respectively electrically connecting to the traces 133 and 134. Thus, the traces 133 and 134 are electrically connected by the passive device 20. The passive device 20 is preferably designed for the surface mount technology to be connected to the traces 133 and 134 via a solder materials 10. When the protection layer 140 is optionally formed as described, the distribution of the solder materials 10 can be limited during surface mount of the passive device 20 in order to prevent solder bridge.

In FIG. 1F, an active device 40, such as a semiconductor chip, an optoelectronic device, or other devices is attached to the base embryo 120a. In this embodiment, the active device 40 is a semiconductor chip. The active device 40 is preferably fixed on the base embryo 120a by an adhesive 30 such as thermosetting epoxy or other materials disposed therebetween.

In FIG. 1G, the active device 40 is electrically connected to the first wiring pattern layer, specifically to at least one of the traces 131 through 134 as desired. In this embodiment, the active device 40 is electrically connected to the traces 131 and 132 by wire-bonding utilizing wires 51 and 52 respectively connecting to the traces 131 and 132. In other embodiments, the active device 40 can be electrically connected to the first wiring pattern layer by flip chip, tape automatic bonding, or other technologies. The active device 40 can be optionally electrically connected to the base embryo 120a utilizing a wire 53 for grounding or heat dissipation.

In FIG. 1H, an encapsulant 150 is formed overlying the top surface 100a of the conductive substrate 100, encapsulating the active device 40, the passive device 20, and the first wiring pattern layer. The encapsulant 150 typically comprises a mixture of thermosetting epoxy and silica fillers, or alternatively, transparent glass and/or transparent epoxy when the active device 40 comprises an optoelectronic device.

Next, the conductive substrate 100 between the base embryo 120a and the first wiring pattern layer is removed from the bottom surface 100b thereof. Note that the step shown in FIG. 1H is exemplary, and not intended to limit the scope of the invention. Those skilled in the art will recognize the possibility of using various methods to achieve the removal of the conductive substrate 100 shown in FIG. 1H.

In FIG. 1H, the resulting package can be flipped when the encapsulant 150 is formed. A third patterned mask layer 113 is formed overlying the bottom surface 100b of the conductive substrate 100, exposing the conductive substrate 100 connecting the base embryo 120a and the first wiring pattern layer. In this embodiment, the third patterned mask layer 113 further exposes the conductive substrate 100 connecting the traces 131 through 134.

Next, the exposed conductive substrate 100 is removed by a method such as etching utilizing the third patterned mask layer 113 as an etch mask, resulting in the remaining conductive substrate 100 underlying the base embryo 120a acting as parts thereof, and parts of the remaining conductive substrate 100 respectively acting as pad embryos 101a and 103a, and a conducting device 102 electrically connecting the first wiring pattern layer. The conducting device 102 can electrically connect to at least one of the traces 131 through 134 as desired. Alternatively, a plurality of the conducting devices 102 can be formed for respective electrical connection between two or more of the traces 131 through 134. In this embodiment, a conducting device 102 is formed, electrically connecting to the trace 132 not electrically connecting to the passive device 20. In this embodiment, further, the pad embryos 101a and 103a respectively electrically connect the traces 131 and 134 which are at the edges of the package. The third patterned mask layer 113 is then removed as shown in FIG. 1I.

In FIG. 1J, a first dielectric layer 161 is formed among the base embryo 120a, the conducting device 102, and the pad embryos 101a and 103a by stencil printing, or alternatively, utilizing the remaining conductive substrate 100, such as the base embryo 120a, the pad embryos 101a and 103a, and the conducting device 102, as a mask to prevent unwanted circuit bridging.

Next, the base embryo 120a and the pad embryos 101a and 103a are thickened, and a second wiring pattern layer electrically connecting the conducting device 102 is formed overlying the first dielectric layer 161. Note that the step shown in FIG. 1J is exemplary, and not intended to limit the scope of the invention. Those skilled in the art will recognize the possibility of using various methods to achieve the thickening of the base embryo 120a and the pad embryos 101a and 103a and the formation of the second wiring pattern layer shown in FIG. 1J.

In FIG. 1J, a fourth patterned mask layer 114 is formed overlying the first dielectric layer 161. The fourth patterned mask layer 114 comprises openings 114a through 114c, wherein the opening 114a exposes the base embryo 120a, the opening 114b exposes the pad embryo 101a, and the opening 114c exposes the pad embryo 103a and a predetermined region for the formation of the second wiring pattern layer. In some cases, the pad embryo 103a and the predetermined region for the formation of the second wiring pattern layer are exposed in different openings.

In FIG. 1J, the base embryo 120a and the pad embryos 101a and 103a are thickened, and the second wiring pattern layer 170 are simultaneously formed in the opening 114c, electrically connecting the conducting device 102 by electroplating, electroless plating, or other disposition methods utilizing the fourth patterned mask layer 114 as a mask. The material utilized for thickening the base embryo 120a and the pad embryos 101a and 103a and forming the second wiring pattern layer 170 is preferably the same as that of the conductive substrate 100, such as copper. The fourth patterned mask layer 114 is then removed as shown in FIG. 1K, followed by forming a second dielectric layer 162 among the base embryo 120a, the second wiring pattern layer 170, and the pad embryos 101a and 103a.

Next, the base embryo 120a and the pad embryos 101a and 103a are thickened, and thus, the active device base 120 and pads 101 and 103 are complete. Note that the step shown in FIG. 1L is exemplary, and not intended to limit the scope of the invention. Those skilled in the art will recognize the possibility of using various methods to achieve the thickening of the base embryo 120a and the pad embryos 101a and 103a shown in FIG. 1L.

In FIG. 1L, a fifth patterned mask layer 115 is formed overlying the second dielectric layer 162 and the second wiring pattern layer 170, exposing the base embryo 120a and the pad embryos 101a and 103a. The base embryo 120a and the pad embryos 101a and 103a are then thickened by electroplating, electroless plating, or other disposition methods utilizing the fifth patterned mask layer 115 as a mask. Thus, the active device base 120 and the pads 101 and 103 are complete. The material utilized for thickening the base embryo 120a and the pad embryos 101a and 103a is preferably the same as that of the conductive substrate 100, such as copper. The fifth patterned mask layer 115 is then removed.

A third dielectric layer 163 can be optionally formed among the active device base 120 and the pads 101 and 103 for preventing unwanted circuit bridge as shown in FIG. 1M, followed by flipping the package back.

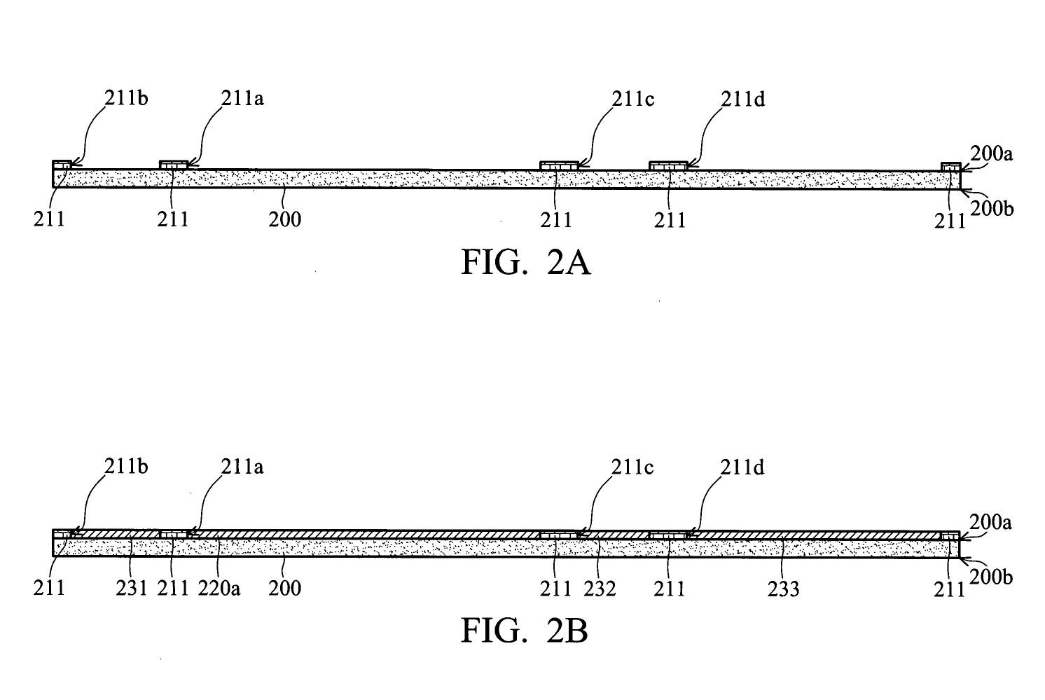

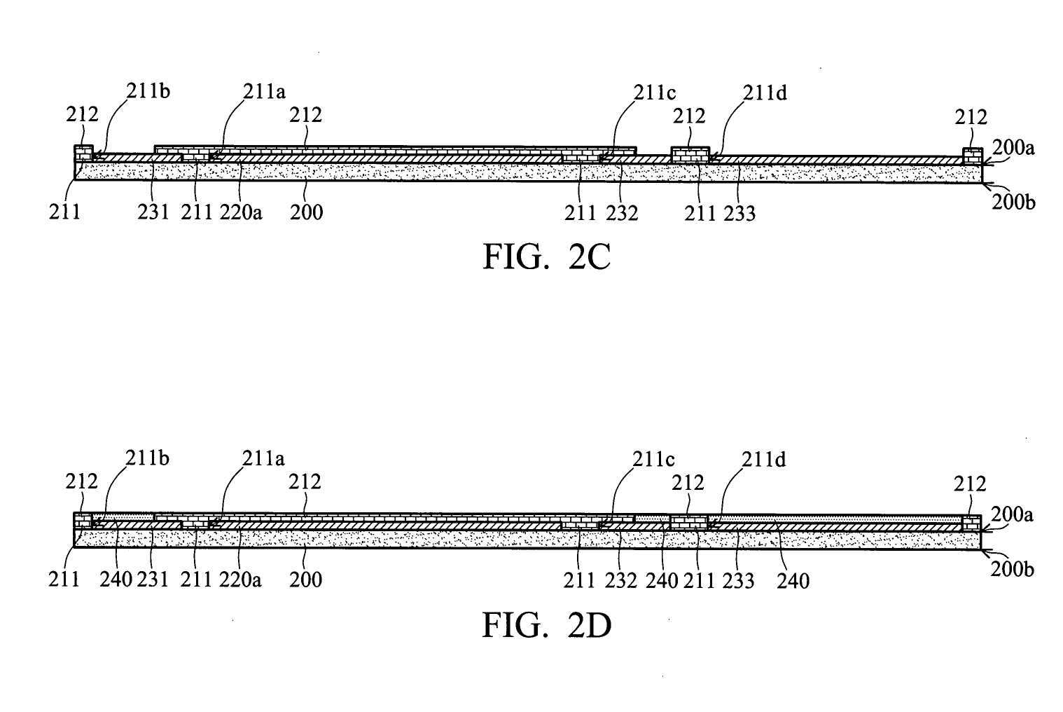

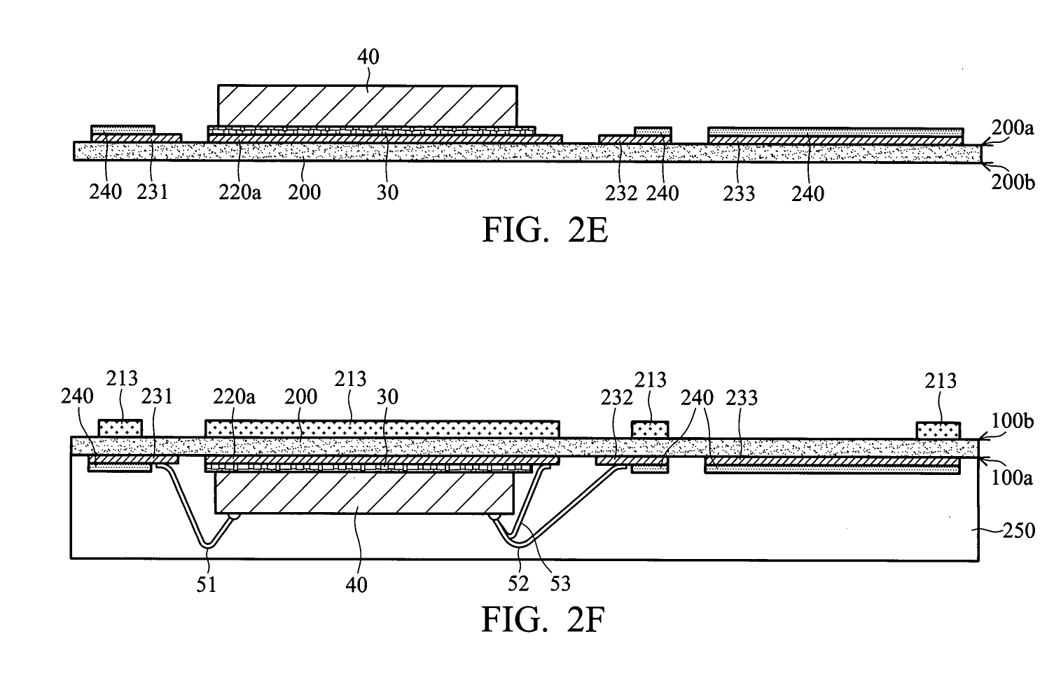

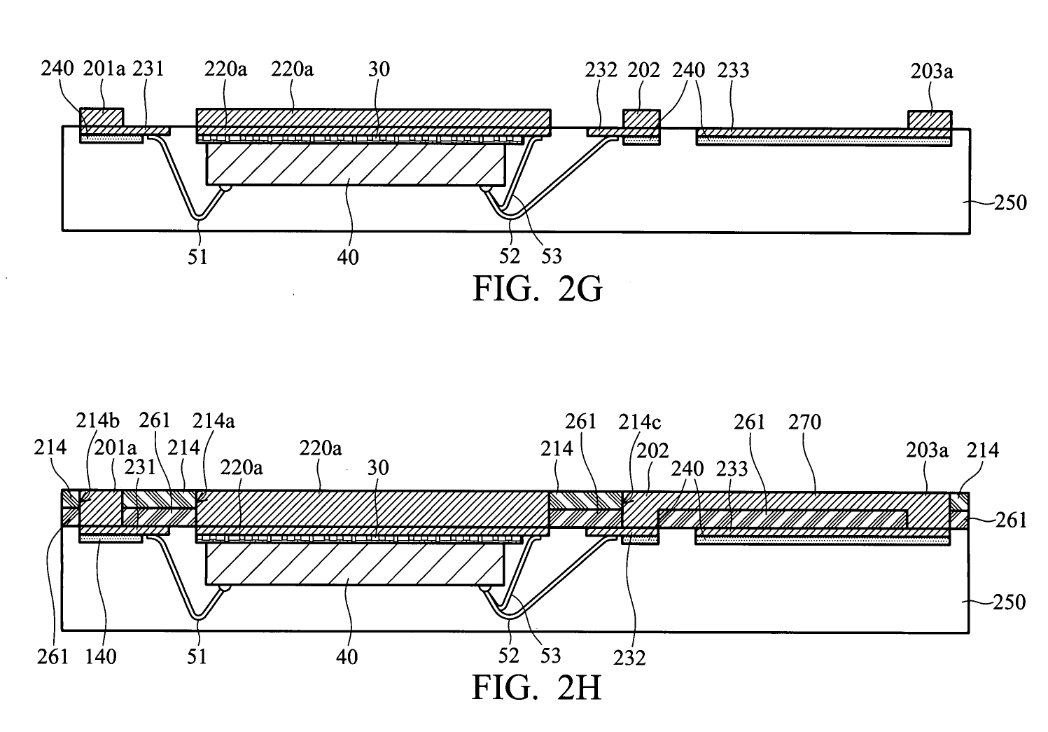

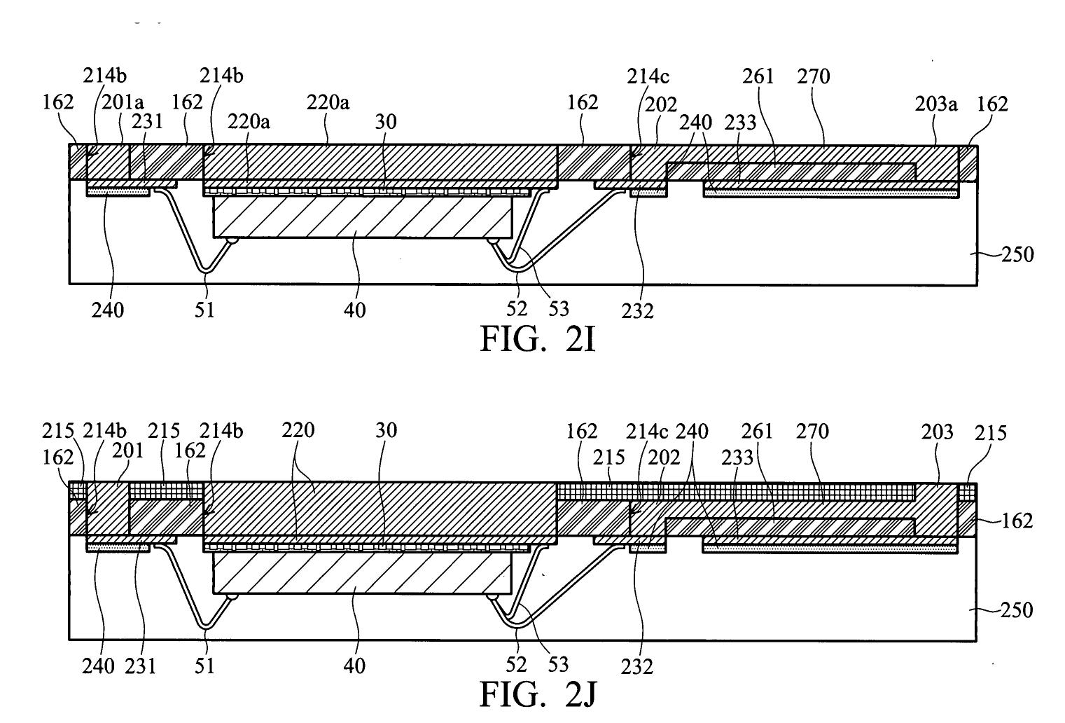

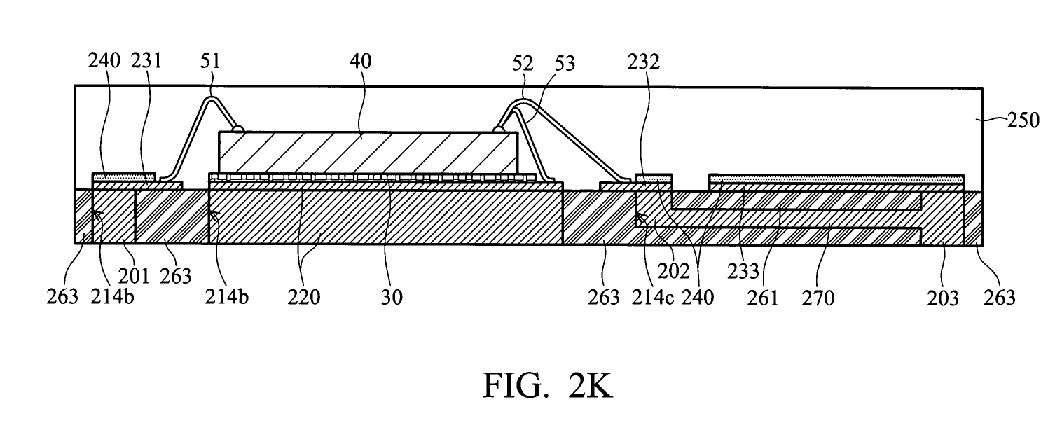

In FIGS. 2A through 2K, cross-sections of a packaging method of a second embodiment of the invention are shown. Compared to the described first embodiment, passive devices are not utilized in this embodiment.

In FIG. 2A, a conductive substrate 200, preferably copper, is provided. The conductive substrate 200 comprises a top surface 200a and bottom surface 200b.

A base embryo 220a and a first wiring pattern layer are formed overlying the top surface 200a of the conductive substrate 200 as shown in FIGS. 2A and 2B. Note that the steps shown in FIGS. 2A and 2B are exemplary, and not intended to limit the scope of the invention. Those skilled in the art will recognize the possibility of using various methods to achieve the base embryo 220a and the first wiring pattern layer shown in FIG. 2B.

In FIG. 2A, a first patterned mask layer 211 is formed overlying the top surface 200a of the conductive substrate 200. The first patterned mask layer 211 comprises an opening 211a exposing a predetermined region for an active device base 220 (shown in FIG. 2J), and openings 211b through 211d respectively exposing predetermined regions for every trace in the first wiring pattern layer. The first patterned mask layer 211 is typically formed by coating a resist layer, followed by exposure and development.

In FIG. 2B, the base embryo 220a and traces 231 through 233 of the first wiring pattern layer are formed overlying the exposed top surface 200a of the conductive substrate 200 by electroplating, electroless plating, or other methods. The first wiring pattern layer is formed beyond the base embryo 220a and may comprise a plurality of traces as desired. In this embodiment, the first wiring pattern layer comprises four traces 231 through 233. The base embryo 220a and the first wiring pattern layer are preferably substantially the same material as the conductive substrate 200, such as copper.

Next, an optional protection layer such as a solder mask can be formed overlying the first wiring pattern layer. The protection layer may be formed overlying the base embryo 220a when an active device is attached by flip chip technology, for example. In this embodiment, formation of the protection layer overlying the first wiring pattern layer is exemplified.

In FIG. 2C, a second patterned mask layer or stencil layer 212 is formed overlying the base embryo 220a and the first wiring pattern layer, followed by forming a protection layer 240 overlying the first wiring pattern layer as shown in FIG. 2D by a method such as stencil printing or other methods.

In some embodiments, the protection layer is not formed and the first patterned mask layer 211 is removed, followed by attachment of an active device.

Next, following that shown in FIG. 2D, the second patterned mask layer or stencil layer 212 is removed. The exposed first wiring pattern layer acts as terminals for electrical connection to the subsequently described active 2 device 2. In some cases, a layer (not shown) for anti-corrosion or solder enhancement such as a nickel/gold layer can be coated on the terminals. Further, the removal of the first patterned mask layer 111 can be performed before or after the removal of the second patterned mask layer or stencil layer 112 as desired.

In FIG. 2E, an active device 40, such as a semiconductor chip, an optoelectronic device, or other devices is attached to the base embryo 220a. In this embodiment, the active device 40 is a semiconductor chip. The active device 40 is preferably fixed on the base embryo 220a by an adhesive 30 such as thermosetting epoxy or other materials disposed therebetween.

In FIG. 2F, the active device 40 is electrically connected to the first wiring pattern layer, specifically to at least one of the traces 231 through 233 as desired. In this embodiment, the active device 40 is electrically connected to the traces 231 and 232 by wire-bonding utilizing wires 51 and 52 respectively connecting to the traces 231 and 232. In other embodiments, the active device 40 can be electrically connected to the first wiring pattern layer by flip chip, tape automatic bonding, or other technologies. The active device 40 can be optionally electrically connected to the base embryo 220a utilizing a wire 53 for grounding or heat dissipation.

Next, an encapsulant 250 is formed overlying the top surface 200a of the conductive substrate 200, encapsulating the active device 40 and the first wiring pattern layer. The encapsulant 250 typically comprises a mixture of thermosetting epoxy and silica fillers, or alternatively, transparent glass and/or transparent epoxy when the active device 40 comprises an optoelectronic device.

Next, the conductive substrate 200 between the base embryo 220a and the first wiring pattern layer is removed from the bottom surface 200b thereof. Note that the subsequently described step is exemplary, and not. intended to limit the scope of the invention. Those skilled in the art will recognize the possibility of using various methods to achieve the removal of the conductive substrate 200 subsequently described.

In FIG. 2F, the resulting package can be flipped when the encapsulant 250 is formed. A third patterned mask layer 213 is formed overlying the bottom surface 200b of the conductive substrate 200, exposing the conductive substrate 200 connecting the base embryo 220a and the first wiring pattern layer. In this embodiment, the third patterned mask layer 213 further exposes the conductive substrate 200 connecting the traces 231 through 233.

Next, the exposed conductive substrate 200 is removed by a method such as etching utilizing the third patterned mask layer 213 as an etch mask, resulting in the remaining conductive substrate 200 underlying the base embryo 220a acting as parts thereof, and parts of the remaining conductive substrate 200 respectively acting as pad embryos 201a and 203a, and a conducting device 202 electrically connecting the first wiring pattern layer. The conducting device 202 can electrically connect to at least one of the traces 231 through 233 as desired. Alternatively, a plurality of the conducting devices 202 can be formed for respective electrical connection between two or more of the traces 231 through 233. In this embodiment, a conducting device 202 is formed, electrically connecting to the trace 232. Further, the pad embryos 201a and 203a respectively electrically connect the traces 231 and 233 which are at the edges of the package. The third patterned mask layer 213 is then removed as shown in FIG. 2G.

In FIG. 2H, a first dielectric layer 261 is formed among the base embryo 220a, the conducting device 202, and the pad embryos 201a and 203a by stencil printing, or alternatively, utilizing the remaining conductive substrate 200, such as the base embryo 220a, the pad embryos 201a and 203a, and the conducting device 202, as a mask to prevent unwanted circuit bridging.

Next, the base embryo 220a and the pad embryos 201a and 203a are thickened, and a second wiring pattern layer electrically connecting the conducting device 202 is formed overlying the first dielectric layer 261. Note that the subsequently described step is exemplary, and not intended to limit the scope of the invention. Those skilled in the art will recognize the possibility of using various methods to achieve the thickening of the base embryo 220a and the pad embryos 201a and 203a and the formation of the second wiring pattern layer as subsequently described.

In FIG. 2H, a fourth patterned mask layer 214 is formed overlying the first dielectric layer 261. The fourth patterned mask layer 214 comprises openings 214a through 214c, wherein the opening 214a exposes the base embryo 220a, the opening 214b exposes the pad embryo 201a, and the opening 214c exposes the pad embryo 203a and a predetermined region for the formation of the second wiring pattern layer. In some cases, the pad embryo 203a and the predetermined region for the formation of the second wiring pattern layer are exposed in different openings.

In FIG. 2H, the base embryo 220a and the pad embryos 201a and 203a are thickened, and the second wiring pattern layer 270 are simultaneously formed in the opening 214c, electrically connecting the conducting device 202 by electroplating, electroless plating, or other disposition methods utilizing the fourth patterned mask layer 214 as a mask. The material utilized for thickening the base embryo 220a and the pad embryos 201a and 203a and forming the second wiring pattern layer 270 is preferably the same as that of the conductive substrate 200, such as copper. The fourth patterned mask layer 214 is then removed as shown in FIG. 2I, followed by forming a second dielectric layer 262 among the base embryo 220a, the second wiring pattern layer 270, and the pad embryos 201a and 203a.

Next, the base embryo 220a and the pad embryos 201a and 203a are thickened, and thus, an active device base 220 and pads 201 and 203 are complete. Note that the step shown in FIG. 2J is exemplary, and not intended to limit the scope of the invention. Those skilled in the art will recognize the possibility of using various methods to achieve the thickening of the base embryo 220a and the pad embryos 201a and 203a shown in FIG. 2J.

In FIG. 2J, a fifth patterned mask layer 215 is formed overlying the second dielectric layer 262 and the second wiring pattern layer 270, exposing the base embryo 220a and the pad embryos 201a and 203a. The base embryo 220a and the pad embryos 201a and 203a are then thickened by electroplating, electroless plating, or other disposition methods utilizing the fifth patterned mask layer 215 as a mask. Thus, the active device base 220 and the pads 201 and 203 are complete. The material utilized for thickening the base embryo 220a and the pad embryos 201a and 203a is preferably the same as that of the conductive substrate 200, such as copper. The fifth patterned mask layer 215 is then removed.

A third dielectric layer 263 can be optionally formed among the active device base 220 and the pads 201 and 203 for preventing unwanted circuit bridge as shown in FIG. 2K, followed by flipping the package back.

The efficacy of the inventive packaging methods at providing a conductive substrate as a base, followed by formation of a first wiring layer of a package substrate completion of encapsulation for an active device overlying a top surface of the conductive substrate, and then forming a first wiring layer or more wiring layers and pads overlying a bottom surface of the conductive substrate in order to integrate substrate fabrication and packaging processes, provides reduced process cost, shortened production duration, and improved process yield.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A packaging method, comprising:
providing a conductive substrate comprising a top surface and bottom surface;
forming a base embryo and a first wiring pattern layer beyond the base embryo overlying the top surface of the conductive substrate;
electrically connecting an active device to the first wiring pattern layer;
forming an encapsulant overlying the top surface of the conductive substrate, encapsulating the active device and the first wiring pattern layer;
removing the conductive substrate between the base embryo and the first wiring pattern layer, the remaining conductive substrate underlying the base embryo acting as parts thereof, and parts of the remaining conductive substrate acting as a conducting device and a pad embryo electrically connecting the first wiring pattern layer;
forming a first dielectric layer among the base embryo, the conducting device, and the pad embryo;
thickening the base embryo and pad embryo, and forming a second wiring pattern layer overlying the first dielectric layer;
forming a second dielectric layer among the base embryo, the second wiring pattern layer, and the pad embryo; and
thickening the base embryo and pad embryo, respectively acting as an active device base and a pad.

2. The method as claimed in claim 1, further comprising forming a third dielectric layer between the active device base and the pad.

3. The method as claimed in claim 1, further comprising, prior to electrically connecting the active device, forming a protection layer overlying the first wiring pattern layer, exposing parts thereof for electrically connecting the active device.

4. The method as claimed in claim 1, wherein the active device and the first wiring pattern layer are electrically connected by wire bonding.

5. The method as claimed in claim 1, further comprising electrically connecting the active device and the base embryo.

6. The method as claimed in claim 1, wherein the active device and the base embryo are electrically connected by wire bonding.

7. A packaging method, comprising:
providing a conductive substrate comprising a top surface and bottom surface;
forming a base embryo and a first wiring pattern layer, comprising a plurality of traces, beyond the base embryo overlying the top surface of the conductive substrate;
electrically connecting a passive device between at least two of the traces;
electrically connecting an active device to the first wiring pattern layer;
forming an encapsulant overlying the top surface of the conductive substrate, encapsulating the passive device, the active device, and the first wiring pattern layer;
removing the conductive substrate between the base embryo and the first wiring pattern layer, the remaining conductive substrate underlying the base embryo acting as parts thereof, and parts of the remaining conductive substrate acting as a conducting device and a pad embryo electrically connecting the first wiring pattern layer;
forming a first dielectric layer among the base embryo, the conducting device, and the pad embryo;
thickening the base embryo and pad embryo, and forming a second wiring pattern layer overlying the first dielectric layer;
forming a second dielectric layer among the base embryo, the second wiring pattern layer, and the pad embryo; and
thickening the base embryo and pad embryo, respectively acting as an active device base and a pad.

8. The method as claimed in claim 7, further comprising forming a third dielectric layer between the active device base and the pad.

9. The method as claimed in claim 7, further comprising, prior to electrically connecting the passive device, forming a protection layer overlying the first wiring pattern layer, exposing parts thereof for electrically connecting the passive and active devices.

10. The method as claimed in claim 7, wherein the active device and the first wiring pattern layer are electrically connected by wire bonding.

11. The method as claimed in claim 7, further comprising electrically connecting the active device and the base embryo.

12. The method as claimed in claim 11, wherein the active device and the base embryo are electrically connected by wire bonding.

13. The method as claimed in claim 7, wherein the passive device and the traces are electrically connected by surface mount technology.

14. The method as claimed in claim 7, wherein removal of the conductive substrate further comprises removing the conductive substrate between the traces.

15. The method as claimed in claim 7, wherein the conducting device electrically connects one of the traces not electrically connecting the passive device.
